(19) United States
(12) Patent Application Publication
(10) Pub. No.: US 2023/0260439 A1
(43) Pub. Date: Aug. 17, 2023

(54) METHOD, ELECTRONIC DEVICE, AND STORAGE MEDIUM FOR CONTROLLING OPTICAL SENSOR ON BASIS OF TENSILE INFORMATION OF STRETCHABLE DISPLAY

(71) Applicant: Samsung Electronics Co., Ltd., Suwon-si (KR)

(72) Inventors: Jaesung LEE, Suwon-si (KR); Seungyeop CHOI, Suwon-si (KR); Kyungtae KIM, Suwon-si (KR); Kwangtai KIM, Suwon-si (KR); Donghyun YEOM, Suwon-si (KR)

(21) Appl. No.: 18/303,248

(22) Filed: Apr. 19, 2023

Related U.S. Application Data
(63) Continuation of application No. PCT/KR2021/017827, filed on Nov. 30, 2021.

(30) Foreign Application Priority Data
Dec. 7, 2020 (KR) 10-2020-0169431
Feb. 5, 2021 (KR) 10-2021-0017099

(51) Int. Cl. G09G 3/00; G01L 5/10; G05B 15/02

(52) U.S. Cl. CPC G09G 3/035; G01L 5/10; G05B 15/02

(57) ABSTRACT

An electronic device is provided. The electronic device includes a stretchable display, an optical sensor disposed under or in the stretchable display, a tensile information detection sensor for detecting tensile information of the stretchable display, and at least one processor operatively coupled to the stretchable display, the optical sensor, and the tensile information detection sensor, wherein the at least one processor is configured to identify the tensile information of the stretchable display through the tensile information detection sensor, and identify or adjust, based on the tensile information, a value of an operation parameter of at least one of the optical sensor or the stretchable display, and the at least one of the optical sensor or the stretchable display may be configured to operate based on the identified or adjusted value of the operation parameter.

### CROSS-REFERENCE TO RELATED APPLICATION(S)

This application is a continuation application, claiming priority under § 365(c), of an International application No. PCT/KR2021/017827, filed on Nov. 30, 2021, which is based on and claims the benefit of a Korean patent application number 10-2020-0169431, filed on Dec. 7, 2020, in the Korean Intellectual Property Office, and of a Korean patent application number 10-2021-0017099, filed on Feb. 5, 2021, in the Korean Intellectual Property Office, the disclosure of each of which is incorporated by reference herein in its entirety.

### BACKGROUND

### 1. Field

The disclosure relates to a method, electronic device, and storage medium for controlling an optical sensor located under or in a lower part of a stretchable display.

### 2. Description of Related Art

An electronic device (e.g., a mobile phone) may output stored information as sound or an image. As the integration level of electronic devices increases and ultra-high-speed, large-capacity wireless communication becomes common, a single mobile communication terminal has recently been equipped with various functions. For example, an entertainment function, such as games, a multimedia function, such as music/video play, a communication and security function for mobile banking, or a schedule management or electronic wallet function as well as a communication function are integrated in one electronic device.

A flat display device and a battery are generally mounted in an electronic device, and the electronic device has bar-type, folder-type, or sliding-type appearance due to the shape of the display device or the battery. Recently, an electronic device having a large screen has appeared so that a user may watch images comfortably.

To conveniently carry an electronic device having such a large screen, an electronic device using a stretchable display (or flexible/scalable display) has been commercialized. The electronic device may include the stretchable display and visually provide various screens through the stretchable display.

The above information is presented as background information only to assist with an understanding of the disclosure. No determination has been made, and no assertion is made, as to whether any of the above might be applicable as prior art with regard to the disclosure.

### SUMMARY

When a stretchable display is deformed, a ratio between a light shielding area and a transmitting area per unit area may change. As a result, the transmittance of a display module and the light reception amount of an optical sensor located under or in a lower part of the stretchable display may be changed. The optical sensor with a light reception amount varying in real time according to the deformation of the stretchable display may cause an inefficient operation, a malfunction, or a fatal error in result interpretation.

According to various embodiments of the disclosure, a change in a light reception amount of an optical sensor located under or in a lower part of a stretchable display may be compensated for in response to a light transmittance change which may occur when the stretchable display is deformed.

Aspects of the disclosure are to address at least the above-mentioned problems and/or disadvantages and to provide at least the advantages described below. Accordingly, an aspect of the disclosure is to provide a method, electronic device, and storage medium for controlling an optical sensor located under or in a lower part of a stretchable display.

Additional aspects will be set forth in part in the description which follows and, in part, will be apparent from the description, or may be learned by practice of the presented embodiments.

In accordance with an aspect of the disclosure, an electronic device is provided. The electronic device includes a stretchable display, an optical sensor disposed under or in the stretchable display, a tensile information detection sensor configured to detect tensile information of the stretchable display, and at least one processor operatively connected to the stretchable display, the optical sensor, and the tensile information detection sensor. The at least one processor may be configured to identify the tensile information of the stretchable display through the tensile information detection sensor, and identify or adjust a value of an operation parameter of at least one of the optical sensor or the stretchable display based on the tensile information. The at least one of the optical sensor or the stretchable display may be configured to operate based on the identified or adjusted value of the operation parameter.

In accordance with another aspect of the disclosure, a method of operating an electronic device is provided. The method includes identifying tensile information of a stretchable display through a tensile information detection sensor, identifying or adjusting a value of an operation parameter of at least one of an optical sensor or the stretchable display based on the tensile information, and controlling at least one of the optical sensor or the stretchable display to operate based on the identified or adjusted value of the operation parameter.

According to various embodiments of the disclosure, a non-transitory storage medium stores instructions configured to, when executed by at least one processor, cause the at least one processor to perform at least one operation. The at least one operation includes identifying tensile information of a stretchable display through a tensile information detection sensor, identifying or adjusting a value of an operation parameter of at least one of an optical sensor or the stretchable display based on the tensile information, and controlling at least one of the optical sensor or the stretchable display to operate based on the identified or adjusted value of the operation parameter.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a block diagram illustrating a display module according to an embodiment of the disclosure;

FIG. 3 is a block diagram illustrating an electronic device according to an embodiment of the disclosure;

FIGS. 4A and 4B are diagrams referred to for describing a method of driving a pixel in a stretched state of a stretchable display according to an embodiment of the disclosure;

FIGS. 5A and 5B are diagrams referred to for describing the structure of a stretchable display according to an embodiment of the disclosure;

FIGS. 6A and 6B are diagrams referred to for describing a change in a light reception amount of an optical sensor according to an embodiment of the disclosure;

FIGS. 7A, 7B, 7C, and 7D are diagrams referred to for describing a change in a transmittance of a stretchable display according to various embodiments of the disclosure;

FIG. 8 is a diagram referred to for describing a transmittance of a stretchable display according to an embodiment of the disclosure;

FIG. 9 is a graph illustrating transmittances versus wavelengths in a stretchable display according to an embodiment of the disclosure;

FIG. 10 is a flowchart illustrating a method of controlling an optical sensor based on tensile information of a stretchable display according to an embodiment of the disclosure;

FIG. 11 is a flowchart illustrating a method of controlling an optical sensor based on tensile information of a stretchable display according to an embodiment of the disclosure;

FIG. 12 is a diagram illustrating a method of controlling a light receiving module of an optical sensor based on tensile information of a stretchable display according to an embodiment of the disclosure;

FIG. 13 is a diagram illustrating a method of controlling a light emitting module and a light receiving module of an optical sensor based on tensile information of a stretchable display according to an embodiment of the disclosure;

FIG. 14 is a flowchart illustrating a method of controlling a stretchable display based on tensile information of the stretchable display according to an embodiment of the disclosure;

FIGS. 15, 16A and 16B are diagrams illustrating a method of controlling a stretchable display and an optical sensor based on tensile information of the stretchable display according to various embodiments of the disclosure;

FIG. 17 is a flowchart illustrating a method of controlling an optical sensor based on tensile information of a stretchable display according to an embodiment of the disclosure; and

FIG. 18 is a diagram illustrating a method of controlling an optical sensor based on tensile information of a stretchable display according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

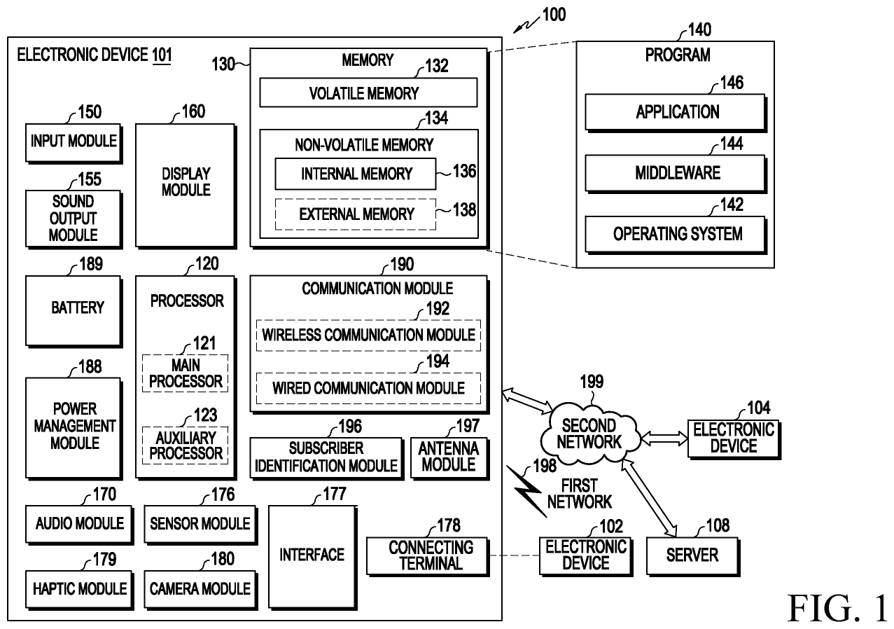

FIG. 1 is a block diagram illustrating an electronic device in a network environment according to an embodiment of the disclosure.

Referring to FIG. 1, an electronic device 101 in a network environment 100 may communicate with an external electronic device 102 via a first network 198 (e.g., a short-range wireless communication network), or at least one of an external electronic device 104 or a server 108 via a second network 199 (e.g., a long-range wireless communication network). According to an embodiment of the disclosure, the electronic device 101 may communicate with the external electronic device 104 via the server 108. According to an embodiment of the disclosure, the electronic device 101 may include a processor 120, a memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments of the disclosure, at least one of the components (e.g., the connecting terminal 178) may be omitted from the electronic device 101, or one or more other components may be added in the electronic device 101. In some embodiments of the disclosure, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment of the disclosure, as at least part of the data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to an embodiment of the disclosure, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an embodiment of the disclosure, the auxiliary processor 123 (e.g., an image signal processor or a communication processor) may be implemented as part of another component (e.g., the camera module 180 or the communication module 190) functionally related to the auxiliary processor 123. According to an embodiment of the disclosure, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment of the disclosure, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment of the disclosure, the display module 160 may include a touch sensor adapted to detect a touch, or a pressure sensor adapted to measure the intensity of force incurred by the touch.

The audio module 170 may convert a sound into an electrical signal and vice versa. According to an embodiment of the disclosure, the audio module 170 may obtain the sound via the input module 150, or output the sound via the sound output module 155 or a headphone of an external electronic device (e.g., the external electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment of the disclosure, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment of the disclosure, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the external electronic device 102). According to an embodiment of the disclosure, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment of the disclosure, the haptic module 179 may include, for example, a motor, a piezoelectric element, or an electric stimulator.

The camera module 180 may capture a still image or moving images. According to an embodiment of the disclosure, the camera module 180 may include one or more lenses, image sensors, image signal processors, or flashes.

The power management module 188 may manage power supplied to the electronic device 101. According to an embodiment of the disclosure, the power management module 188 may be implemented as at least part of, for example, a power management integrated circuit (PMIC).

The battery 189 may supply power to at least one component of the electronic device 101. According to an embodiment of the disclosure, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment of the disclosure, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth-generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth-generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an embodiment of the disclosure, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment of the disclosure, the antenna module 197 may include an antenna including a radiating element including a conductive material or a conductive pattern formed in or on a substrate (e.g., a printed circuit board (PCB)). According to an embodiment of the disclosure, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment of the disclosure, another component (e.g., a radio frequency integrated circuit (RFIC)) other than the radiating element may be additionally formed as part of the antenna module 197. According to various embodiments of the disclosure, the antenna module 197 may form a mmWave antenna module. According to an embodiment of the disclosure, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment of the disclosure, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment of the disclosure, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment of the disclosure, the external electronic device 104 may include an internet-of-things (IoT) device. The server 108 may be an intelligent server using machine learning and/or a neural network. According to an embodiment of the disclosure, the external electronic device 104 or the server 108 may be included in the second network 199. The electronic device 101 may be applied to intelligent services (e.g., smart home, smart city, smart car, or healthcare) based on 5G communication technology or IoT-related technology.

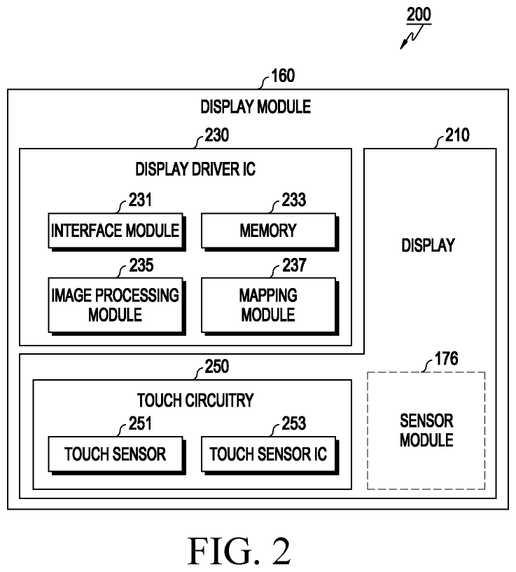

FIG. 2 is a block diagram 200 illustrating a display module according to an embodiment of the disclosure.

Referring to FIG. 2, the display module 160 may include a display 210 and a display driver integrated circuit (DDI) 230 to control the display 210. The DDI 230 may include an interface module 231, a memory 233 (e.g., buffer memory), an image processing module 235, or a mapping module 237. The DDI 230 may receive image information that contains image data or an image control signal corresponding to a command to control the image data from another component of the electronic device 101 via the interface module 231. For example, according to an embodiment of the disclosure, the image information may be received from the processor 120 (e.g., the main processor 121 (e.g., an application processor)) or the auxiliary processor 123 (e.g., a graphics processing unit) operated independently from the function of the main processor 121. The DDI 230 may communicate, for example, with a touch circuitry 250 or the sensor module 176 via the interface module 231. The DDI 230 may also store at least part of the received image information in the memory 233, for example, on a frame by frame basis. The image processing module 235 may perform pre-processing or post-processing (e.g., adjustment of resolution, brightness, or size) with respect to at least part of the image data. According to an embodiment of the disclosure, the pre-processing or post-processing may be performed, for example, based at least in part on one or more characteristics of the image data or one or more characteristics of the display 210. The mapping module 237 may generate a voltage value or a current value corresponding to the image data pre-processed or post-processed by the image processing module 235. According to an embodiment of the disclosure, the generating of the voltage value or current value may be performed, for example, based at least in part on one or more attributes of the pixels (e.g., an array, such as a red green blue (RGB) stripe or a pentile structure, of the pixels, or the size of each subpixel). At least some pixels of the display 210 may be driven, for example, based at least in part on the voltage value or the current value such that visual information (e.g., a text, an image, or an icon) corresponding to the image data may be displayed via the display 210.

According to an embodiment of the disclosure, the display module 160 may further include the touch circuitry 250. The touch circuitry 250 may include a touch sensor 251 and a touch sensor IC 253 to control the touch sensor 251. The touch sensor IC 253 may control the touch sensor 251 to detect a touch input or a hovering input with respect to a certain position on the display 210. To achieve this, for example, the touch sensor 251 may detect (e.g., measure) a change in a signal (e.g., a voltage, a quantity of light, a resistance, or a quantity of one or more electric charges) corresponding to the certain position on the display 210. The touch circuitry 250 may provide input information (e.g., a position, an area, a pressure, or a time) indicative of the touch input or the hovering input detected via the touch sensor 251 to the processor 120. According to an embodiment of the disclosure, at least part (e.g., the touch sensor IC 253) of the touch circuitry 250 may be formed as part of the display 210 or the DDI 230, or as part of another component (e.g., the auxiliary processor 123) disposed outside the display module 160.

According to an embodiment of the disclosure, the display module 160 may further include at least one sensor (e.g., a fingerprint sensor, an iris sensor, a pressure sensor, or an illuminance sensor) of the sensor module 176 or a control circuit for the at least one sensor. In such a case, the at least one sensor or the control circuit for the at least one sensor may be embedded in one portion of a component (e.g., the display 210, the DDI 230, or the touch circuitry 250)) of the display module 160. For example, when the sensor module 176 embedded in the display module 160 includes a biometric sensor (e.g., a fingerprint sensor), the biometric sensor may obtain biometric information (e.g., a fingerprint image) corresponding to a touch input received via a portion of the display 210. As another example, when the sensor module 176 embedded in the display module 160 includes a pressure sensor, the pressure sensor may obtain pressure information corresponding to a touch input received via a partial or whole area of the display 210. According to an embodiment of the disclosure, the touch sensor 251 or the sensor module 176 may be disposed between pixels in a pixel layer of the display 210, or over or under the pixel layer.

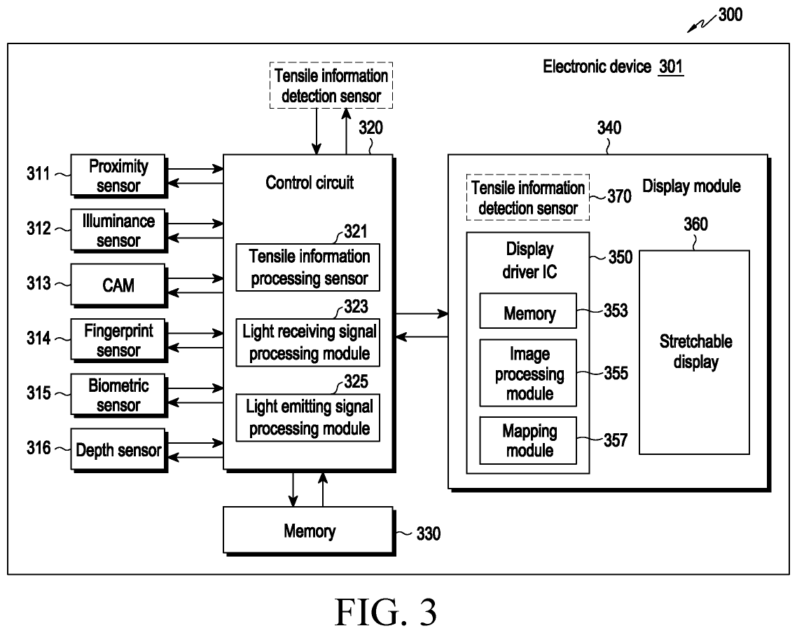

FIG. 3 is a block diagram 300 illustrating an electronic device according to an embodiment of the disclosure.

Referring to FIG. 3, an electronic device 301 may include a plurality of optical sensors 311 to 316, a tensile information detection sensor 370, a control circuit 320, a memory 330, and a display module 340. Hereinafter, the optical sensor may also be referred to as a light sensor.

According to various embodiments of the disclosure, the electronic device 301 may be implemented to include more components or fewer components, not limited to the devices illustrated in FIG. 3. For example, the electronic device 301 may be implemented to further include the components described above with reference to FIG. 1 or FIG. 2. The term ‘— block’ used below refers to a unit that processes at least one function or operation, and may be implemented in hardware or software or in a combination of hardware and software.

The plurality of optical sensors 311 to 316 may include a proximity sensor 311, an illuminance sensor 312, a camera 313, a fingerprint sensor 314, a biometric sensor 315, and a depth sensor 316. The depth sensor 316 may also be referred to as a three-dimensional (3D) sensor and include a structured light (SL)-type depth sensor or a time of flight (ToF)-type depth sensor.

The display module 340 may include a stretchable display 360 and a display driver IC (DDI) 350 for controlling the stretchable display 360. The DDI 350 may include a memory 353 (e.g., buffer memory), an image processing module 355, and/or a mapping module 357.

According to various embodiments of the disclosure, the display module 340 may include more components or fewer components, not limited to the devices illustrated in FIG. 3. For example, the display module 340 may be implemented to further include the components of the display module 160 described before with reference to FIG. 2.

The DDI 350 may receive image information including, for example, image data or an image control signal corresponding to a command for controlling the image data through an interface module (the interface module 231 of FIG. 2) from another component of the electronic device 301.

The DDI 350 may store at least part of the received image information in the memory 353, for example, in frames.

The image processing module 355 may pre-process or post-process (e.g., adjust a resolution, a brightness, or a size) at least part of the image data based on characteristics of the image data or characteristics of the stretchable display 360.

The mapping module 357 may generate a voltage value or current value corresponding to the image data pre-processed or post-processed through the image processing module 355.

At least some pixels of the stretchable display 360 may be driven at least partially based on the voltage value or current value, so that visual information (e.g., text, an image, or an icon) corresponding to the image data is displayed through the stretchable display 360.

According to an embodiment of the disclosure, the display module 340 may further include a tensile information detection sensor 370 and a control circuit therefor. In this case, the tensile information detection sensor 370 or the control circuit therefor may be embedded in part of the display module 340 (e.g., the stretchable display 360 or the DDI 350) or part of a touch circuit (the touch circuit 250 of FIG. 2). According to an embodiment of the disclosure, the tensile information detection sensor 370 may be disposed between pixels of a pixel layer of the display 210 or over or under the pixel layer.

The tensile information detection sensor 370 may detect tensile information of the stretchable display 360. For example, the tensile information detection sensor 370 may output tensile information including a stretching ratio, a stretching degree/level/value, a value representing a stretching length/volume/amount of the stretchable display 360, or a closed state (or inserted state) or open state (or extended state) of at least part of the stretchable display 360. According to an embodiment of the disclosure, the tensile information detection sensor 370 may be disposed outside the display module 340 (e.g., in a mechanism/structure supporting the display module 340) and operatively connected to the control circuit 320.

According to an embodiment of the disclosure, the tensile information detection sensor 370 may detect the closed state (or inserted state) or open state (or extended state) of at least part of the stretchable display 360. For example, at least part of the stretchable display 360 may be closed inside or inserted into a housing (or a structure) of the electronic device 301 in a normal state (i.e., a state in which no force is applied from the outside and thus no stretching occurs), and may be exposed or extended to the outside of the housing (or the structure) of the electronic device 301 in a stretched state (i.e., a state in which force is applied from the outside and stretching occurs). According to an embodiment of the disclosure, the tensile information detection sensor 370 may include a Hall sensor, a switch element that operates mechanically, or a photo detector. For example, the Hall sensor may be disposed in the housing (or the structure), and a magnet may be disposed on at least part of the stretchable display 360 (or a movable structure supporting the same). In another example, the mechanical switch element may be disposed in the housing (or the structure), and a recess or protrusion that may engage or interfere with the switch element may be disposed in at least part of the stretchable display 360 (or the movable structure supporting the same). In another example, the photo detector may be disposed in the housing (or the structure), and an optical pattern may be disposed in at least part of the stretchable display 360 (or the movable structure supporting the same).

The memory 330 may store various data used by at least one component (e.g., the control circuit 320, the display module 340, or the tensile information detection sensor 370) of the electronic device 301. The data may include, for example, input data or output data for software and its related command.

The control circuit 320 may include a tensile information processing module 321, a light receiving signal processing module 323, and a light emitting signal processing module 325. According to an embodiment of the disclosure, the control circuit 320 may include at least one processor (e.g., the processor 120).

The tensile information processing module 321 may receive the tensile information of the stretchable display from the tensile information detection sensor 370 and identify the received tensile information. The tensile information processing module 321 may identify (or adjust/change) a value of at least one operation parameter of an optical sensor or the stretchable display 360 based on the tensile information. The tensile information processing module 321 may transmit the identified value of the operation parameter to the light receiving signal processing module 323, when the identified value of the operation parameter is related to a light receiving operation (or a light receiving signal/module). The tensile information processing module 321 may transmit the identified value of the operation parameter to the light emitting signal processing module 325, when the identified value of the operation parameter is related to a light emitting operation (or a light emitting signal/module).

The light receiving signal processing module 323 may receive the value of the operation parameter related to the light receiving operation from the tensile information processing module 321, and transmit a control signal including or corresponding to the value of the operation parameter to one of the plurality of optical sensors 311 to 316. The optical sensor receiving the control signal including the value of the operation parameter may operate a light receiving module according to the value of the operation parameter.

The light emitting signal processing module 325 may receive the value of the operation parameter related to the light emitting operation from the tensile information processing module 321, and transmit a control signal including or corresponding to the value of the operation parameter to the stretchable display 360 or one of the plurality of optical sensors 311 to 316. The optical sensor receiving the control signal including the value of the operation parameter may operate a light emitting module according to the value of the operation parameter.

According to various embodiments of the disclosure, an electronic device (e.g., the electronic device 101 or the electronic device 301) may include a stretchable display (e.g., the display 210 or the display module 340), an optical sensor (e.g., the plurality of optical sensors 311 to 316) disposed under or in the stretchable display, a tensile information detection sensor (e.g., the tensile information detection sensor 370) configured to detect tensile information of the stretchable display, and at least one processor (e.g., the processor 120 or the control circuit 320) operatively connected to the stretchable display, the optical sensor, and the tensile information detection sensor. The at least one processor may be configured to identify the tensile information of the stretchable display through the tensile information detection sensor, and identify (or adjust/change) a value of an operation parameter of at least one of the optical sensor or the stretchable display based on the tensile information. The at least one of the optical sensor or the stretchable display may be configured to operate based on the value of the operation parameter.

According to various embodiments of the disclosure, the optical sensor may include a camera, a fingerprint sensor, an illuminance sensor, a proximity sensor, a 3D sensor, an iris sensor, or a photoplethysmography (PPG) sensor.

According to various embodiments of the disclosure, the operation parameter may include at least one of a light emission intensity (a Tx intensity), a light emission pulse frequency (a Tx pulse frequency), a light emission pulse duty cycle (a Tx pulse on duty), a light emission time.

According to various embodiments of the disclosure, the operation parameter may include at least one of a sensor gain value, a shutter speed, an exposure time (an integration time), or a signal processing-related variable value (e.g., a filter coefficient).

According to various embodiments of the disclosure, the stretchable display may include a plurality of pixels. Some of the plurality of pixels may be turned off in a normal state of the stretchable display and turned on in a stretched state of the stretchable display.

According to various embodiments of the disclosure, the stretchable display may include backplanes for driving pixels and signal lines disposed between the pixels, and a spacing between the backplanes (and/or length(s) of the backplanes) may increase in the stretched state of stretchable display.

According to various embodiments of the disclosure, the stretchable display may further include a stretchable substrate configured to support the backplanes.

According to various embodiments of the disclosure, the backplanes may be disposed to contact each other in the normal state of the stretchable display.

According to various embodiments of the disclosure, the backplanes may be spaced apart by a predetermined spacing in the normal state of the stretchable display.

According to various embodiments of the disclosure, the stretchable substrate may be configured to have a hole aligned with a backplane open area between the backplanes in the stretched state of the stretchable display.

According to various embodiments of the disclosure, at least part of the stretchable substrate may be made of a transparent material.

According to various embodiments of the disclosure, at least part of the stretchable substrate may be made of a transparent material, and at least one transparent part of the stretchable substrate may be disposed to be aligned with a backplane open area between the backplanes in the stretched state of the stretchable display.

According to various embodiments of the disclosure, the value of the operation parameter may be determined to correspond to a value related to a stretching degree of the stretchable display.

According to various embodiments of the disclosure, the value of the operation parameter may be determined to correspond to a value related to a transmittance change of the stretchable display or a value related to a change in a light reception amount detected by the optical sensor.

According to various embodiments of the disclosure, the value of the operation parameter may be determined to be proportional to or inversely proportional to a value related to a transmittance change of the stretchable display or a value related to a change in a light reception amount detected by the optical sensor.

According to various embodiments of the disclosure, at least one of light emission power or a gain value of the optical sensor may be determined to be proportional to or inversely proportional to a value related to a transmittance change of the stretchable display or a value related to a change in a light reception amount detected by the optical sensor.

According to various embodiments of the disclosure, at least one of light emission power or a gain value of the optical sensor may be determined to be proportional to or inversely proportional to a square of a value related to a transmittance change of the stretchable display or a value related to a change in a light reception amount detected by the optical sensor.

According to various embodiments of the disclosure, at least one of a light emission intensity, a light emission pulse frequency, a light emission pulse duty cycle, or a light emission time of the stretchable display may be determined based on a value related to a stretching degree of the stretchable display.

According to various embodiments of the disclosure, the at least one processor may identify the value of the operation parameter corresponding to a value representing a stretching degree included in the tensile information, based on a table including values representing stretching degrees and values of an operation parameter.

According to various embodiments of the disclosure, the at least one processor may identify a value related to a transmittance change of the stretchable display or a value related to a change in a light reception amount detected by the optical sensor, which corresponds to a value representing a stretching degree included in the tensile information, based on a table including values representing stretching degrees, values related to transmittance changes, or values related to changes in a light reception amount, and determine the value of the operation parameter based on the identified value.

According to various embodiments of the disclosure, the at least one processor may identify a value related to a transmittance change of the stretchable display or a value related to a change in a light reception amount detected by the optical sensor, which corresponds to a value representing a stretching degree included in the tensile information, based on a first table including values representing stretching degrees, values related to transmittance changes, or values related to changes in a light reception amount, and determine the value of the operation parameter based on the identified value, based on a second table including values representing stretching degrees, values related to transmittance changes or values related to changes in a light reception amount, and values of an operation parameter.

According to various embodiments of the disclosure, the at least one processor may be configured to compare a value representing a stretching degree included in the tensile information with a preset threshold value, and when the value representing the stretching degree is equal to or greater than the threshold value, control at least one of the optical sensor or the stretchable display to operate based on the value of the operation parameter.

According to various embodiments of the disclosure, when the value representing the stretching degree included in the tensile information is equal to or greater than the threshold value, at least one of the optical sensor or the stretchable display may be configured to operate based on the value of the operation parameter.

According to various embodiments of the disclosure, the at least one processor may be configured to compare a value representing a stretching degree included in the tensile information with a preset threshold value, and when the value representing the stretching degree reaches the threshold value, control at least one of the optical sensor or the stretchable display to operate based on the value of the operation parameter.

According to various embodiments of the disclosure, when the value representing the stretching degree included in the tensile information reaches the threshold value, at least one of the optical sensor or the stretchable display may be configured to operate based on the value of the operation parameter.

According to various embodiments of the disclosure, when the tensile information indicates an open state of the stretchable display, the at least one processor may be configured to control the optical sensor or the stretchable display to operate based on the value of the operation parameter.

According to various embodiments of the disclosure, when the tensile information indicates the open state of the stretchable display, at least one of the optical sensor or the stretchable display may be configured to operate based on the value of the operation parameter.

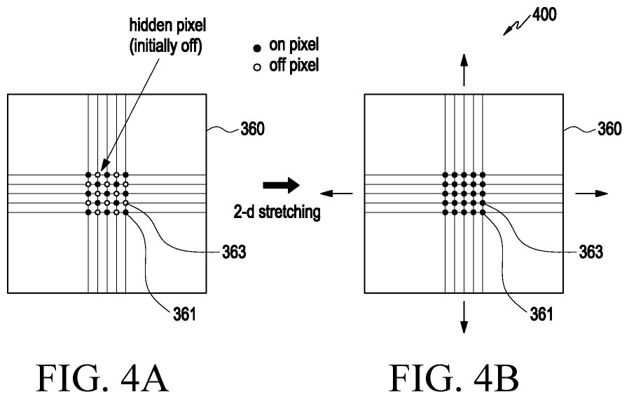

FIGS. 4A and 4B are diagrams 400 referred to for describing a method of driving a pixel in a stretched state of a stretchable display according to an embodiment of the disclosure.

Referring to FIG. 4A, the stretchable display 360 may include a plurality of pixels 361 and 363. In the normal state of the stretchable display 360, some 361 of the plurality of pixels 361 and 363 may be turned on, and others 363 of the plurality of pixels 361 and 363 may be turned off.

Referring to FIG. 4B, in the stretched state of the stretchable display 360, the pixels 361 of the plurality of pixels 361 and 363 may be kept turned on, and the other pixels 363 of the plurality of pixels 361 and 363 may switch from a turn-off state to a turn-on state.

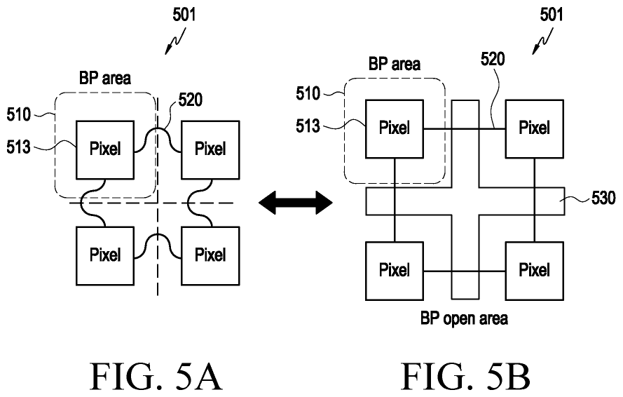

FIGS. 5A and 5B are diagrams referred to for describing the structure of a stretchable display according to an embodiment of the disclosure.

Referring to FIG. 5A, a stretchable display 501 may include a plurality of backplane areas 510 and signal lines 520 disposed between the plurality of backplane areas 510. When a display surface is viewed, each backplane area 510 may include a corresponding pixel 513. In the normal state of the stretchable display 501, the backplane areas 510 may be in close contact with each other (a spacing of 0) or spaced apart from each other by a preset first spacing (a spacing greater than 0). The backplane areas 510 may refer to backplanes with pixels mounted on top surfaces thereof.

Referring to FIG. 5B, in the stretched state of the stretchable display 501, the first spacing between the backplane areas 510 may be changed to a second spacing (a spacing greater than the first spacing). As the spacing between the backplane areas 510 (and/or the length(s) of the backplanes) increases, a backplane open area 530 may be formed between the backplane areas 510 or the volume of the backplane open area 530 may be increased.

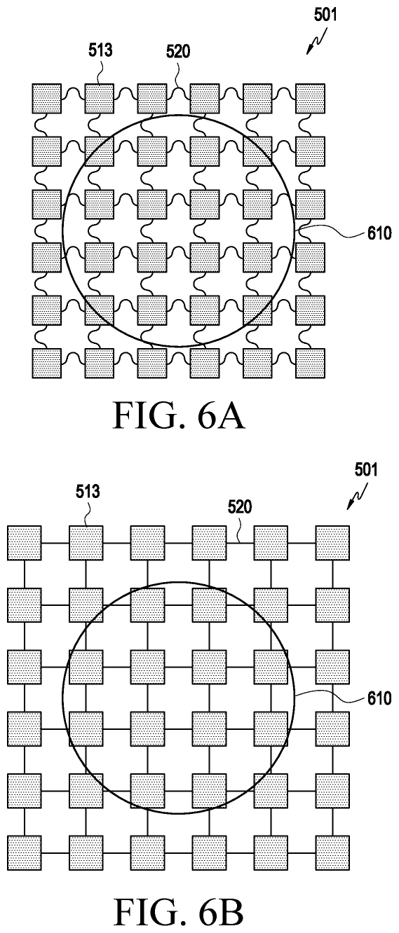

FIGS. 6A and 6B are diagrams referred to for describing a change in a light reception amount of an optical sensor according to an embodiment of the disclosure.

Referring to FIG. 6A, in the normal state of the stretchable display 501, the pixels 513 of the backplane areas (or the backplane areas 510) may be spaced apart from each other by a preset third spacing (a spacing greater than 0). In the normal state of the stretchable display 501, a light transmission area 610 corresponding to an optical sensor (e.g., the optical sensors 311 to 316) (or a light receiving module) may have a fixed size.

Referring to FIG. 6B, in the stretched state of the stretchable display 501, the third spacing between the pixels 513 may be changed to a fourth spacing (a spacing greater than the third spacing). As the spacing between the pixels 513 (or the backplane areas 510) increases, an area occupied by the pixels 513 (or the backplane areas 510) or the signal lines 520 in the light transmission area 610 (or per unit area) may be reduced, and the light transmission area 610 may maintain the fixed size. As the area occupied by the pixels 513 (or the backplane areas 510) or the signal lines 520 in the light transmission area 610 is reduced (and the area of a transmission area/high transmittance area is increased), the light reception amount of the optical sensor may be changed (i.e., increased) even under the condition that the amount and intensity of external light incident from the outside do not change. Hereinafter, transmittance may also be referred to as light transmittance.

This phenomenon (i.e., a phenomenon in which a strain rate and a transmittance are proportional to each other) may also occur in a wearable stretchable sensor that detects a strain rate through a change in a light transmittance. For example, when a stretchable sensor generated by forming an opaque carbon nanotube (CNT) on top of an elastomer called Ecoflex is stretched, a light transmittance may increase while micro cracks are formed in the CNT.

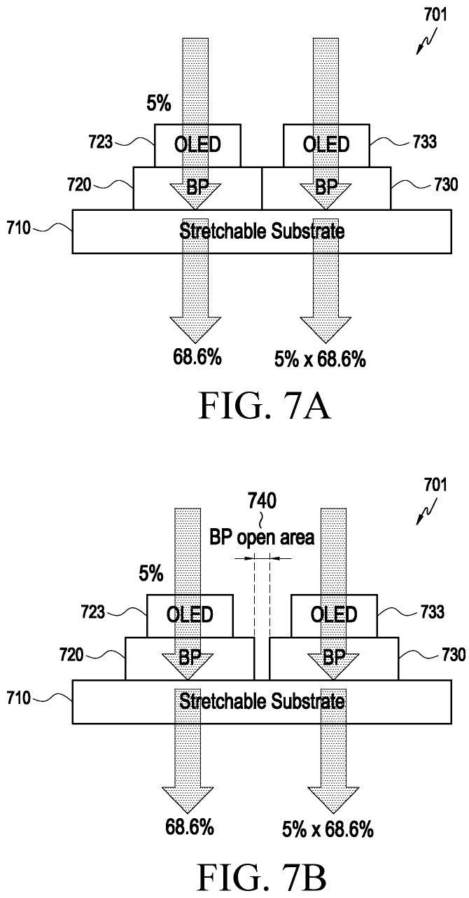

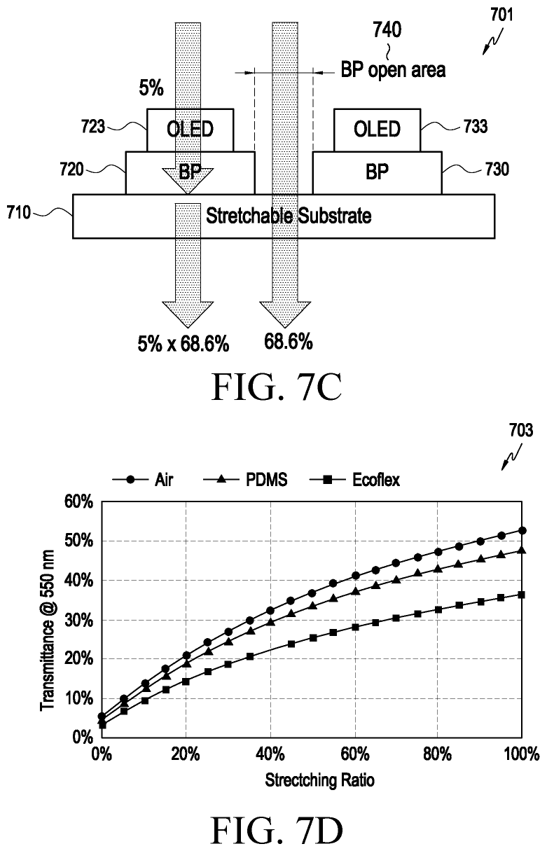

FIGS. 7A, 7B, 7C, and 7D are diagrams referred to for describing a transmittance change of a stretchable display according to various embodiments of the disclosure.

Referring to FIG. 7A, a stretchable display 701 may include a plurality of backplanes 720 and 730 with OLED pixels 723 and 733 mounted on top surfaces thereof, which drive the pixels 723 and 733, and a stretchable substrate 710 with the backplanes 720 and 730 mounted on a top surface thereof. In the normal state of the stretchable display 701, the backplanes 720 and 730 may be in close contact with each other (a spacing of 0). Hereinafter, the stretchable display 701 may also be referred to as a stretchable OLED display.

Referring to FIG. 7B, in the normal state of the stretchable display 701, the backplanes 720 and 730 may be spaced apart from each other by a first preset spacing (a spacing greater than 0). According to an embodiment of the disclosure, the stretchable display 701 may not include the stretchable substrate 710. For example, the transmittance of the backplanes 720 and 730 made of polyimide (PI) on which the OLED pixels 723 and 733 are mounted may be 5%, and the transmittance of the stretchable substrate 710 may be 68.6% when made of ecoflex. The transmittance of the combination of the backplanes 720 and 730 made of PI on which the OLED pixels 723 and 733 are mounted and the stretchable substrate 710 made of ecoflex may be calculated to be 5%*68.6%.

Referring to FIG. 7C, in the stretched state of the stretchable display 701, a first spacing (or a spacing of 0) between the backplanes 720 and 730 may be changed to a second spacing (a spacing greater than the first spacing). As the spacing between the backplanes 720 and 730 increases, a backplane open area 740 may be formed between the backplanes 720 and 730 or the volume/length of the backplane open area 740 may increase.

According to an embodiment of the disclosure, in the stretched state of the stretchable display 701, the stretchable substrate 710 may be configured to have at least one hole aligned with the backplane open area 740 between the backplanes 720 and 730.

According to an embodiment of the disclosure, at least part of the stretchable substrate 710 may be made of a transparent material.

According to an embodiment of the disclosure, in the stretched state of the stretchable display 701, the stretchable substrate 710 may be configured to have at least one transparent part aligned with the backplane open area 740 between the backplanes 720 and 730.

FIG. 7D is a graph 703 illustrating stretching ratios versus transmittances in the stretchable display 701.

The graph 703 illustrates the results of simulating transmittance changes per unit area according to stretching of an active area in the stretchable OLED display 701 with a PI substrate having 373 pixels per inch (PPI). The separate stretchable substrate 710 (made of a material, such as ecoflex or PDMS) supporting the backplanes 720 and 730 may or may not exist (air).

When the stretchable substrate 710 is excluded, the transmittance of the backplanes 720 and 730 made of PI on which the OLED pixels 723 and 733 are mounted is 5% before stretching, and the optical sensor may perform sensing accordingly. When the stretching ratio is 100%, that is, when the area of the stretchable display 701 is doubled, the light transmittance of the stretchable display 701 may increase to about 52.5%. This is a 10-fold increase value of the light transmittance from before the stretching. When the stretchable substrate 710 physically supports the backplanes 720 and 730, a transmittance variation may vary depending on a material. In the graph 703, the transmittance of the stretchable substrate 710 is assumed to be 68.6% for ecoflex and 90.0% for PDMS, and thickness reduction according to a Poisson's ratio is not considered. If a thickness decrease and a transmittance increase caused by the Poisson's ratio are additionally considered, the transmittance may be higher than the results of the graph 703.

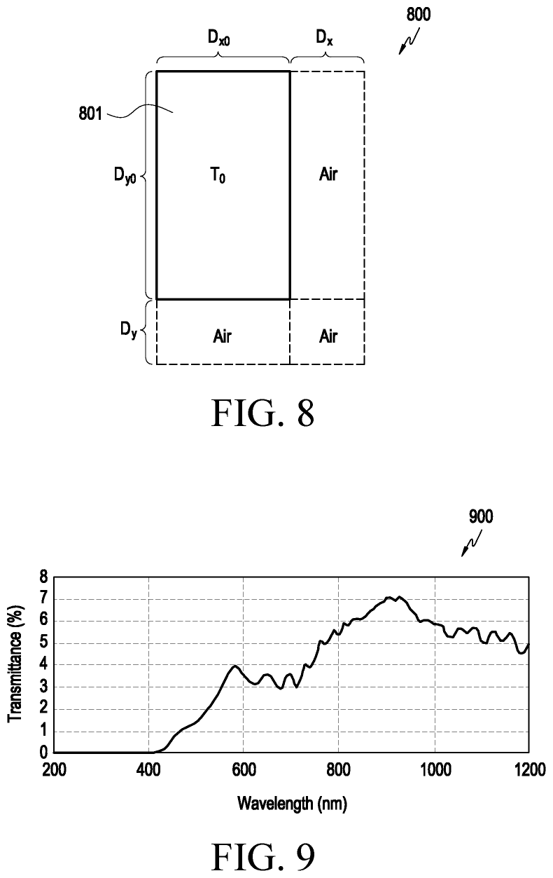

FIG. 8 is a diagram 800 referred to for describing a transmittance of a stretchable display according to an embodiment of the disclosure.

Referring to FIG. 8, a change in a light transmittance T according to a strain rate of a stretchable display 801 may be estimated as shown in Equation 1 below. A light transmittance increase according to an x-axis (horizontal direction) strain rate and a y-axis (vertical direction) strain rate may be calculated by Equation 1.

$$T = {T}_{0} \times \frac{{D}_{x 0} {D}_{y 0}}{( {D}_{x 0} + {D}_{x} ) ( {D}_{y 0} + {D}_{y} )} + 1 \times \frac{{D}_{x0} {D}_{y} + {D}_{x} {D}_{y 0} + {D}_{x} {D}_{y}}{( {D}_{x 0} + {D}_{x} ) ( {D}_{y 0} + {D}_{y} )} \qquad Equation 1$$

In Equation 1, T represents the transmittance of the stretchable display 801 after deformation, T0 represents the transmittance (e.g., BP area transmittance) of the stretchable display 801 before the deformation, Dx and Dy represent length variations in x-axis and y-axis directions, respectively, and Dx0 and Dy0 represent initial lengths in the x-axis and y-axis directions, respectively.

A change in the light reception amount of the optical sensor may be compensated for based on Equation 1. Factors (e.g., a sensor gain, a shutter speed, an exposure time, or a signal processing-related variable value) that affect a light receiving signal S and factors (e.g., a light emission intensity (Tx intensity), a light emission pulse frequency (Tx pulse frequency), a light emission pulse duty cycle (Tx pulse on duty), or a light emission time) affecting a light emitting signal may be adjusted in inverse proportion to a change in the transmittance according to stretching of the stretchable display 801. For example, when the transmittance increases due to the stretching of the stretchable display 801, the light reception gain of the light receiving module may be lowered, the light emission intensity of the light emitting module may be weakened, or the light emission time may be reduced.

Optical sensors that require this adjustment may include image sensors (CCD and CMOS), an illuminance sensors, a proximity sensor, an SL-type or ToF-type 3D sensor (or depth sensor), an iris recognition sensor, a photoplethysmography (PPG) sensor, and so on.

FIG. 9 is a graph 900 illustrating transmittances versus wavelengths in a stretchable display according to an embodiment of the disclosure.

Referring to FIG. 9, the graph 900 represents the transmittance of a stretchable OLED display (e.g., the stretchable OLED display 701) with respect to the wavelength of light incident on the stretchable OLED display.

As illustrated in Table 1 below, since each optical sensor may use a different wavelength, and the transmittance of the stretchable display may be different depending on the wavelength of light, a transmittance variation according to the wavelength used by each optical sensor may be used to adjust the value of an operation parameter of the optical sensor.

TABLE 1

| Sensor Type | Wavelength Used |
|---|---|
| CCD image sensor | 470 nm, 560 nm, 600 nm |
| CMOS image sensor | 420 nm, 530 nm, 670 nm |
| Illuminance sensor, fingerprint sensor | 550 nm |
| Proximity sensor, iris recognition sensor, TOF, SL | 940 nm |
| PPG | 440 nm, 550 nm, 660 nm, 940 nm |

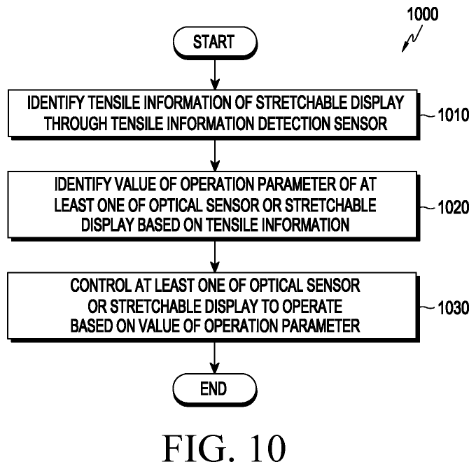

FIG. 10 is a flowchart 1000 illustrating a method of controlling an optical sensor based on tensile information of a stretchable display according to an embodiment of the disclosure.

Referring to FIG. 10, according to various embodiments of the disclosure, the operations illustrated in FIG. 10 may be performed in various orders, not limited to the illustrated order. According to various embodiments of the disclosure, more operations than those illustrated in FIG. 10 may be performed, or at least one operation fewer than those illustrated in FIG. 10 may be performed.

An electronic device (e.g., the electronic device 101 or the electronic device 301) or at least one processor (e.g., the processor 120 or the control circuit 320) may perform at least one of operations 1010 to 1030.

In operation 1010, the electronic device may identify tensile information of a stretchable display (e.g., the stretchable display 360, the stretchable display 501, or the stretchable display 701) through a tensile information detection sensor (e.g., the tensile information detection sensor 370). The tensile information detection sensor may be disposed between pixels of a pixel layer of the stretchable display or over or under the pixel layer. Alternatively, the tensile information detection sensor may be disposed outside the stretchable display (e.g., in a mechanism/structure supporting the stretchable display). The tensile information detection sensor may detect the tensile information of the stretchable display. For example, the tensile information detection sensor may output tensile information including a stretching ratio, a stretching degree/level/value, a value representing a stretching length/volume/amount of the stretchable display 360, or a closed state (or inserted state) or open state (or extended state) of at least part of the stretchable display.

In operation 1020, the electronic device may identify (or adjust/change) a value of at least one operation parameter of at least one of an optical sensor (e.g., the optical sensors 311 to 316) or the stretchable display based on the tensile information. The optical sensor may include a proximity sensor, an illuminance sensor, a camera, a fingerprint sensor, a biometric sensor, and a depth sensor. The operation parameter may include at least one of a light emission intensity, a light emission pulse frequency, a light emission pulse duty cycle, a light emission time, a sensor gain value, a shutter speed, an exposure time, or a signal processing-related variable value (e.g., a filter coefficient).

In operation 1030, the electronic device may control at least one of the optical sensor or the stretchable display to operate based on the value of the operation parameter.

According to various embodiments of the disclosure, a method of controlling an optical sensor based on tensile information of a stretchable display (e.g., the display 210 or the display module 340) by an electronic device (e.g., the electronic device 101 or the electronic device 301) may include identifying (or adjust/change) the tensile information of the stretchable display through a tensile information detection sensor (e.g., the tensile information detection sensor 370), identifying a value of an operation parameter of at least one of the optical sensor or the stretchable display based on the tensile information, and controlling at least one of the optical sensor or the stretchable display to operate based on the value of the operation parameter.

According to various embodiments of the disclosure, the value of the operation parameter may be determined to correspond to a value related to a stretching degree of the stretchable display.

According to various embodiments of the disclosure, the value of the operation parameter may be determined to correspond to a value related to a transmittance change of the stretchable display or a value related to a change in a light reception amount detected by the optical sensor.

According to various embodiments of the disclosure, the value of the operation parameter may be determined to be proportional to or inversely proportional to a value related to a transmittance change of the stretchable display or a value related to a change in a light reception amount detected by the optical sensor.

According to various embodiments of the disclosure, at least one of light emission power or a gain value of the optical sensor may be determined to be proportional to or inversely proportional to a value related to a transmittance change of the stretchable display or a value related to a change in a light reception amount detected by the optical sensor.

According to various embodiments of the disclosure, at least one of light emission power or a gain value of the optical sensor may be determined to be proportional to or inversely proportional to a square of a value related to a transmittance change of the stretchable display or a value related to a change in a light reception amount detected by the optical sensor.

According to various embodiments of the disclosure, at least one of a light emission intensity, a light emission pulse frequency, a light emission pulse duty cycle, or a light emission time of the stretchable display may be determined based on a value related to a stretching degree of the stretchable display.

According to various embodiments of the disclosure, identifying the tensile information of the stretchable display may include identifying the value of the operation parameter corresponding to a value representing a stretching degree included in the tensile information, based on a table including values representing stretching degrees and values of an operation parameter.

According to various embodiments of the disclosure, identifying the tensile information of the stretchable display may include identifying a value related to a transmittance change of the stretchable display or a value related to a change in a light reception amount detected by the optical sensor, which corresponds to a value representing a stretching degree included in the tensile information, based on a table including values representing stretching degrees, values related to transmittance changes, or values related to changes in a light reception amount, and determining the value of the operation parameter based on the identified value.

According to various embodiments of the disclosure, controlling the at least one of the optical sensor or the stretchable display may include comparing a value representing a stretching degree included in the tensile information with a preset threshold value, and when the value representing the stretching degree is equal to or greater than the threshold value, controlling at least one of the optical sensor or the stretchable display to operate based on the value of the operation parameter.

According to various embodiments of the disclosure, controlling the at least one of the optical sensor or the stretchable display may include comparing a value representing a stretching degree included in the tensile information with a preset threshold value, and when the value representing the stretching degree reaches the threshold value, controlling at least one of the optical sensor or the stretchable display to operate based on the value of the operation parameter.

According to various embodiments of the disclosure, controlling the at least one of the optical sensor or the stretchable display may include, when the tensile information indicates an open state of the stretchable display, controlling the optical sensor or the stretchable display to operate based on the value of the operation parameter.

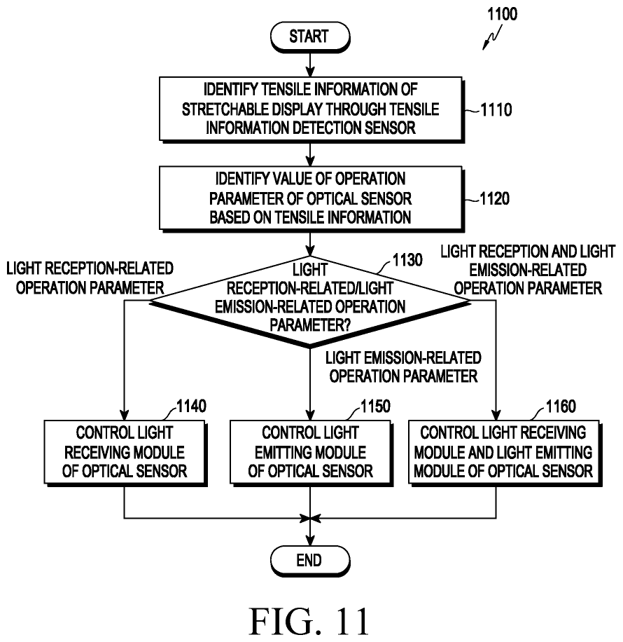

FIG. 11 is a flowchart 1100 illustrating a method of controlling an optical sensor based on tensile information of a stretchable display according to an embodiment of the disclosure.

Referring to FIG. 11, according to various embodiments of the disclosure, the operations illustrated in FIG. 11 may be performed in various orders, not limited to the illustrated order. According to various embodiments of the disclosure, more operations than those illustrated in FIG. 11 may be performed, or at least one operation fewer than those illustrated in FIG. 11 may be performed.

An electronic device (e.g., the electronic device 101 or the electronic device 301) or at least one processor (e.g., the processor 120 or the control circuit 320) may perform at least one of operations 1110 to 1160.

In operation 1110, the electronic device may identify tensile information of a stretchable display (e.g., the stretchable display 360, the stretchable display 501, or the stretchable display 701) through a tensile information detection sensor (e.g., the tensile information detection sensor 370). The tensile information detection sensor may be disposed between pixels of a pixel layer of the stretchable display or over or under the pixel layer. The tensile information detection sensor may detect the tensile information of the stretchable display. For example, the tensile information detection sensor may output tensile information including a stretching ratio, a stretching degree/level/value, a value representing a stretching length/volume/amount of the stretchable display 360, or a closed state (or inserted state) or open state (or extended state) of at least part of the stretchable display.

In operation 1120, the electronic device may identify (or adjust/change) a value of at least one operation parameter of at least one of an optical sensor (e.g., the optical sensors 311 to 316) or the stretchable display based on the tensile information. The optical sensor may include a proximity sensor, an illuminance sensor, a camera, a fingerprint sensor, a biometric sensor, and a depth sensor. The operation parameter may include at least one of a light emission intensity, a light emission pulse frequency, a light emission pulse duty cycle, a light emission time, a sensor gain value, a shutter speed, an exposure time, or a signal processing-related variable value. In operation 1120, the electronic device may first determine an operation parameter related to light emission based on the tensile information, and then determine an operation parameter related to light reception based on the tensile information and the determined operation parameter related to light emission. In another embodiment of the disclosure, an operation parameter related to light reception may be first determined based on the tensile information, and then an operation parameter related to light emission may be determined based on the tensile information and the determined operation parameter related to light reception. In another embodiment of the disclosure, a pair of operation parameters related to light emission and operation parameters related to light reception may be simultaneously determined based on the tensile information.

In operation 1130, the electronic device may identify whether the operation parameter identified in operation 1120 is a light reception-related operation parameter or a light emission-related operation parameter.

The electronic device may perform operation 1140 when the identified operation parameter is a light reception-related operation parameter, perform operation 1150 when the identified operation parameter is a light emission-related operation parameter, and perform operation 1160 when the identified operation parameter is an operation parameter related to light reception and light emission.

In operation 1140, the electronic device may control the light receiving module of the optical sensor to operate according to the identified value of the operation parameter. According to an embodiment of the disclosure, the electronic device may output a control signal including or corresponding to the value of the operation parameter to the optical sensor, and the light receiving module of the optical sensor may operate according to the value of the operation parameter.

In operation 1150, the electronic device may control the light emitting module of the optical sensor to operate according to the identified value of the operation parameter. According to an embodiment of the disclosure, the electronic device may output a control signal including or corresponding to the value of the operation parameter to the optical sensor, and the light emitting module of the optical sensor may operate according to the value of the operation parameter.

In operation 1160, the electronic device may control the light receiving module and the light emitting module of the optical sensor to operate according to the identified value of the operation parameter. According to an embodiment of the disclosure, the electronic device may output a control signal including or corresponding to values of operation parameters to the optical sensor, and the light receiving module and the light emitting module of the optical sensor may operate according to the values of the operation parameters.

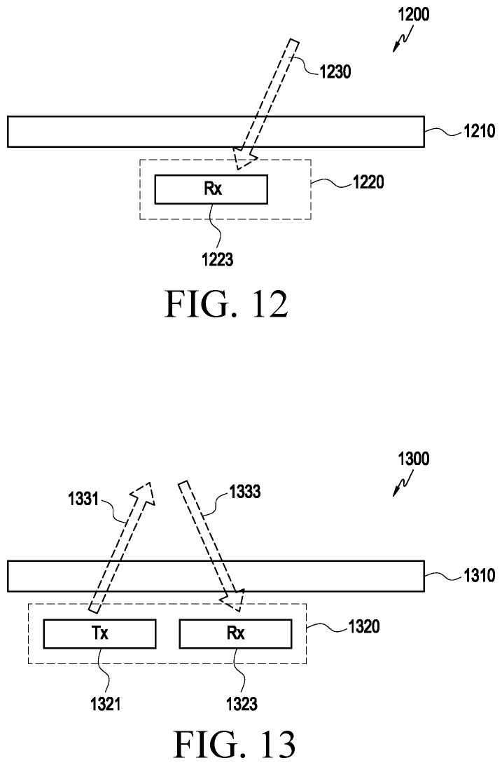

FIG. 12 is a diagram 1200 illustrating a method of controlling a light receiving module of an optical sensor based on tensile information of a stretchable display according to an embodiment of the disclosure.

Referring to FIG. 12, an optical sensor 1220 (e.g., a camera, an illuminance sensor, or the like) including a light receiving module 1223 may be disposed under a stretchable display 1210. External light 1230 may pass through the stretchable display 1210 and enter the light receiving module 1223 of the optical sensor 1220. The light receiving module 1223 may output a light receiving signal corresponding to the incident light. In the stretched state of the stretchable display 1210, at least one processor (e.g., the processor 120 or the control circuit 320) may transmit a value of an operation parameter for adjusting a gain value of the light receiving module 1223 to the optical sensor 1220. The light receiving module 1223 of the optical sensor 1220 may operate to output a light receiving signal with a gain value set according to the value of the operation parameter. According to an embodiment of the disclosure, the gain value of the light receiving module 1223 may be adjusted in proportion to or in inverse proportion to a value related to a change in the transmittance of the stretchable display 1210 or a value related to a change in a light reception amount detected by the optical sensor. For example, the value related to the transmittance change may be T0/T where T0 is the transmittance of the stretchable display 1210 in the normal state, and T is the transmittance of the stretchable display 1210 in the stretched state. For example, the value related to the change in the light reception amount may be S0/S where S0 is a light reception amount (or the intensity/magnitude/voltage/power of the light receiving signal) in the normal state of the stretchable display 1210, and S is a light reception amount in the stretched state of the stretchable display 1210.

FIG. 13 is a diagram 1300 illustrating a method of controlling a light emitting module and a light receiving module of an optical sensor based on tensile information of a stretchable display according to an embodiment of the disclosure.

Referring to FIG. 13, an optical sensor 1320 (e.g., a proximity sensor, a depth sensor (TOF or SL), a face recognition camera, a PPG, or the like) including a light emitting module 1321 and a light receiving module 1323 may be disposed under the stretchable display 1310. First light 1331 output from the light emitting module 1321 of the optical sensor 1320 may pass through the stretchable display 1310 and be output to the outside. Second light 1333 from the outside may pass through the stretchable display 1310 and enter the light receiving module 1323 of the optical sensor 1320. The light receiving module 1323 may output a light receiving signal corresponding to the incident second light 1333. In the stretched state of the stretchable display 1310, at least one processor (e.g., the processor 120 or the control circuit 320) may output a value of an operation parameter for adjusting the output power of the light emitting module 1321 to the optical sensor 1320. The light emitting module 1321 of the optical sensor 1320 may operate to output the first light 1331 (or a light emitting signal) with output power set according to the value of the operation parameter. In the stretched state of the stretchable display 1310, the at least one processor may output a value of an operation parameter for adjusting the gain value of the light receiving module 1323 to the optical sensor 1320. The light receiving module 1323 of the optical sensor 1320 may operate to output a light receiving signal with a gain value set according to the value of the operation parameter. According to an embodiment of the disclosure, the output power of the light emitting module 1321 and the gain value of the light receiving module 1323 may be adjusted in proportion to or in inverse proportion to a value related to a change in the transmittance of the stretchable display 1210 or a value related to a change in a light reception amount detected by the optical sensor. According to an embodiment of the disclosure, one of the output power of the light emitting module 1321 and the gain value of the light receiving module 1323 may be adjusted in proportion to or in inverse proportion to the square of the value related to the change in the transmittance of the stretchable display 1210 or the square of the value related to the change in the light reception amount detected by the optical sensor. For example, the value related to the transmittance change may be T0/T where T0 is the transmittance of the stretchable display 1310 in the normal state, and T is the transmittance of the stretchable display 1310 in the stretched state. For example, the value related to the change in the light reception amount may be S0/S where S0 is a light reception amount (or the intensity/magnitude/voltage/power of the light receiving signal) in the normal state of the stretchable display 1310, and S is a light reception amount in the stretched state of the stretchable display 1310.

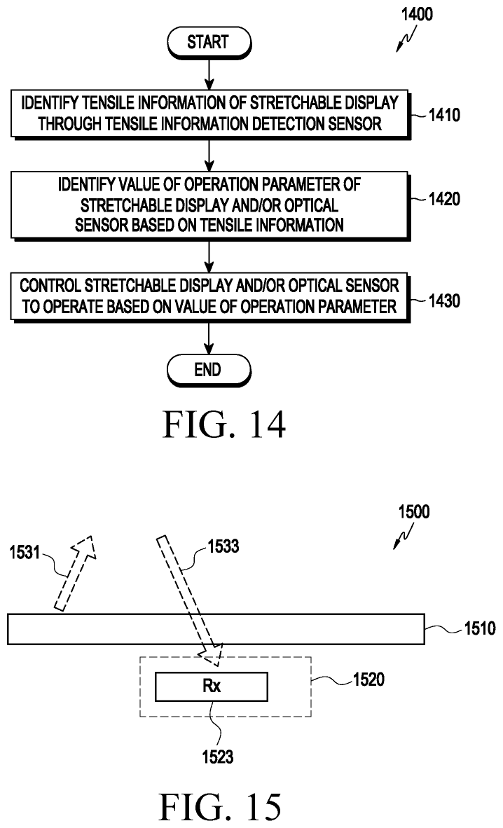

FIG. 14 is a flowchart 1400 illustrating a method of controlling a stretchable display based on tensile information of the stretchable display according to an embodiment of the disclosure.

Referring to FIG. 14, according to various embodiments of the disclosure, the operations illustrated in FIG. 14 may be performed in various orders, not limited to the illustrated order. According to various embodiments of the disclosure, more operations than those illustrated in FIG. 14 may be performed, or at least one operation fewer than those illustrated in FIG. 14 may be performed.

An electronic device (e.g., the electronic device 101 or the electronic device 301) or at least one processor (e.g., the processor 120 or the control circuit 320) may perform at least one of operations 1410 to 1430.

In operation 1410, the electronic device may identify tensile information of a stretchable display (e.g., the stretchable display 360, the stretchable display 501, or the stretchable display 701) through a tensile information detection sensor (e.g., the tensile information detection sensor 370). The tensile information detection sensor may be disposed between pixels of a pixel layer of the stretchable display or over or under the pixel layer. The tensile information detection sensor may detect the tensile information of the stretchable display. For example, the tensile information detection sensor may output tensile information including a stretching ratio, a stretching degree/level/value, a value representing a stretching length/volume/amount of the stretchable display, or a closed state (or inserted state) or open state (or extended state) of at least part of the stretchable display.

In operation 1420, the electronic device may identify (or adjust/change) a value of an operation parameter of the stretchable display and/or an optical sensor (e.g., the optical sensors 311 to 316) based on the tensile information. The operation parameter of the stretchable display may include at least one of a light emission intensity, a light emission pulse frequency, a light emission pulse duty cycle, a light emission time or output power, or a brightness of the stretchable display (or a partial area (some pixels) of the stretchable display aligned with the optical sensor). The operation parameter of the optical sensor may include at least one of a sensor gain value, a shutter speed, an exposure time, or a signal processing-related variable value.

In operation 1430, the electronic device may control the stretchable display and/or the optical sensor to operate based on the value of the operation parameter.

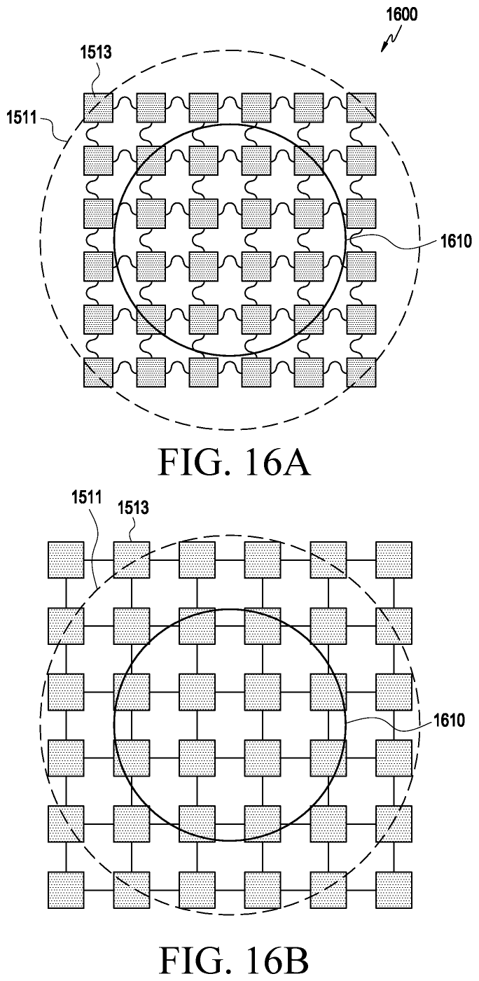

FIGS. 15, 16A, and 16B, are diagrams 1500 and 1600 referred to for describing a method of controlling a stretchable display and an optical sensor based on tensile information of a stretchable display according to various embodiments of the disclosure.

Referring to FIG. 15, an optical sensor 1520 including a light receiving module 1520 may be disposed under the stretchable display 1510. A partial area (some pixels) of the stretchable display 1510 aligned with a light transmission area 1610 corresponding to the light receiving module 1523 of the optical sensor 1520 may function as a light emission source on behalf of a light emitting module of the optical sensor 1520. First light 1531 output from the stretchable display 1510 may be output to the outside. Second light 1533 from the outside may pass through the stretchable display 1510 and enter the light receiving module 1523 of the optical sensor 1520. The light receiving module 1523 may output a light receiving signal corresponding to the incident second light 1533. In the stretched state of the stretchable display 1510, at least one processor (e.g., the processor 120 or the control circuit 320) may output a value of an operation parameter of the stretchable display 1510 to the stretchable display 1510. The stretchable display 1510 may operate to output the first light 1531 (or a light emitting signal) with a light emission intensity, a light emission pulse frequency, a light emission pulse duty cycle, a light emission time, or a brightness (or output power) set according to the value of the operation parameter. In the stretched state of the stretchable display 1510, the at least one processor may output a value of an operation parameter for adjusting the gain value of the light receiving module 1523 to the optical sensor 1520. The light receiving module 1523 of the optical sensor 1520 may operate to output a light receiving signal with a gain value set according to the value of the operation parameter. According to an embodiment of the disclosure, the output power/brightness of the stretchable display 1510 and the gain value of the light receiving module 1523 may be adjusted in proportion to or in inverse proportion to a value related to a change in the transmittance of the stretchable display 1510 or a value related to a change in a light reception amount detected by the optical sensor. According to an embodiment of the disclosure, one of the output power/brightness of the stretchable display 1510 and the gain value of the light receiving module 1523 may be adjusted in proportion to or in inverse proportion to the square of the value related to the change in the transmittance of the stretchable display 1510 or the square of the value related to the change in the light reception amount detected by the optical sensor. For example, the value related to the transmittance change may be T0/T, and the value related to the change in the light reception amount may be S0/S.

Referring to FIGS. 16A and 16B, pixels 1513 of a partial area 1511 of the stretchable display 1510 aligned with the light transmission area 1610 corresponding to the optical sensor 1520 (or the light receiving module 1523) may function as a light emission source.

Referring to FIG. 16A, in the normal state of the stretchable display 1510, pixels 1513 may be spaced apart from each other by a preset first spacing (a spacing greater than 0). In the normal state of the stretchable display 1510, a light transmission area 1610 may have a fixed size.

Referring to FIG. 16B, in the stretched state of the stretchable display 1510, the first spacing between the pixels 1513 may be changed to a second spacing (a spacing greater than the first spacing). As the spacing between the pixels 1513 increases, an area occupied by the pixels 1513 in the light transmission area 1610 (or per unit area) may be reduced, and the light transmission area 1610 may maintain the fixed size. As the spacing between the pixels 1513 increases, the resolution of the stretchable display 1510 may decrease in proportion to 1/{(1+Dx)(1+Dy)}, and an electronic device (e.g., the electronic device 101 or the electronic device 301) or at least one processor (e.g., the processor 120 or the control circuit 320) may control the stretchable display 1510 to maintain a light intensity per unit area by increasing the output power/brightness of the stretchable display 1510 in proportion to (1+Dx)(1+Dy).

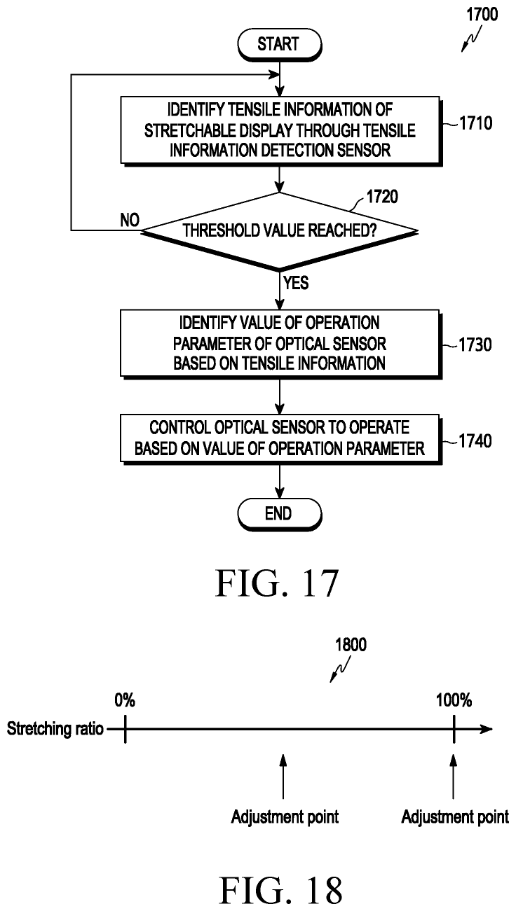

FIG. 17 is a flowchart 1700 illustrating a method of controlling an optical sensor based on tensile information of a stretchable display according to an embodiment of the disclosure.

Referring to FIG. 17, according to various embodiments of the disclosure, the operations illustrated in FIG. 17 may be performed in various orders, not limited to the illustrated order. According to various embodiments of the disclosure, more operations than those illustrated in FIG. 17 may be performed, or at least one operation fewer than those illustrated in FIG. 17 may be performed.

An electronic device (e.g., the electronic device 101 or the electronic device 301) or at least one processor (e.g., the processor 120 or the control circuit 320) may perform at least one of operations 1710 to 1740.

In operation 1710, the electronic device may identify tensile information of a stretchable display (e.g., the stretchable display 360, the stretchable display 501, or the stretchable display 701) through a tensile information detection sensor (e.g., the tensile information detection sensor 370). The tensile information detection sensor may be disposed between pixels of a pixel layer of the stretchable display or over or under the pixel layer. The tensile information detection sensor may detect the tensile information of the stretchable display. For example, the tensile information detection sensor may output tensile information including a stretching ratio, a stretching degree/level/value, a value representing a stretching length/volume/amount of the stretchable display, or a closed state (or inserted state) or open state (or extended state) of at least part of the stretchable display.

In operation 1720, the electronic device may compare a value representing the stretching degree included in the tensile information with a preset threshold value, and identify whether the value representing the stretching degree reaches (or matches) the threshold value. The electronic device may perform operation 1730 when the value representing the stretching degree reaches the threshold value, and may repeat operation 1710 when the value representing the stretching degree does not reach the threshold value.

According to an embodiment of the disclosure, the electronic device may perform operation 1730, when the value representing the stretching degree is equal to or greater than the threshold value.

According to an embodiment of the disclosure, the electronic device may perform operation 1730, when the value representing the stretching degree indicates the open state of the stretchable display.

In operation 1730, when the value representing the stretching degree reaches the threshold value, the electronic device may identify (or adjust/change) a value of an operation parameter of an optical sensor (e.g., the optical sensors 311 to 316) based on the tensile information. The optical sensor may include a proximity sensor, an illuminance sensor, a camera, a fingerprint sensor, a biometric sensor, and a depth sensor. The operation parameter may include at least one of a light emission intensity, a light emission pulse frequency, a light emission pulse duty cycle, a light emission time, a sensor gain value, a shutter speed, an exposure time, or a signal processing-related variable value.

In operation 1740, the electronic device may control the optical sensor to operate based on the value of the operation parameter.

FIG. 18 is a diagram 1800 illustrating a method of controlling an optical sensor based on tensile information of a stretchable display according to an embodiment of the disclosure.

Referring to FIG. 18, an operation parameter of an optical sensor (e.g., the optical sensors 311 to 316) may be adjusted at a plurality of points according to a stretching ratio. When the operation parameter is adjusted using a table, values between the respective adjustment points may be obtained through interpolation. The table may include reference stretching ratios (or reference values indicating stretching degree) and values of operation parameters. When a stretching ratio received from the tensile information detection sensor is not retrieved from the table, an intermediate value between operation parameter values corresponding to reference stretching ratios adjacent to the received stretching ratio in the table may be determined as an adjustment value. According to an embodiment of the disclosure, stretching ratios other than predetermined adjustment points may be ignored. For example, when predetermined adjustment points related to an illuminance sensor are stretching ratios of 0%, 50%, and 100%, a dynamic parameter of the illuminance sensor may not be adjusted at points with a stretching ratio of 25% or 75%.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 140) including one or more instructions that are stored in a storage medium (e.g., an internal memory 136 or of the disclosure external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment of the disclosure, a method according to various embodiments of the disclosure may be included and provided in a computer program product. The computer program product may be traded as a product between a seller and a buyer. The computer program product may be distributed in the form of a machine-readable storage medium (e.g., a compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities, and some of the multiple entities may be separately disposed in different components. According to various embodiments of the disclosure, one or more of the above-described components may be omitted, or one or more other components may be added. Alternatively or additionally, a plurality of components (e.g., modules or programs) may be integrated into a single component. In such a case, according to various embodiments of the disclosure, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a stretchable display;
an optical sensor disposed under or in the stretchable display;
a tensile information detection sensor configured to detect tensile information of the stretchable display; and
at least one processor operatively connected to the stretchable display, the optical sensor, and the tensile information detection sensor,
wherein the at least one processor is configured to:
identify the tensile information of the stretchable display through the tensile information detection sensor, and
identify or adjust a value of an operation parameter of at least one of the optical sensor or the stretchable display based on the tensile information, and
wherein the at least one of the optical sensor or the stretchable display is configured to operate based on the identified or adjusted value of the operation parameter.

2. The electronic device of claim 1, wherein the optical sensor includes a camera, a fingerprint sensor, an illuminance sensor, a proximity sensor, a three-dimensional (3D) sensor, an iris sensor, or a photoplethysmography (PPG) sensor.

3. The electronic device of claim 1, wherein the operation parameter includes at least one of a light emission intensity, a light emission pulse frequency, a light emission pulse duty cycle, a light emission time, a sensor gain value, a shutter speed, an exposure time, or a signal processing-related variable value.

4. The electronic device of claim 1,
wherein the stretchable display includes:
pixels;
backplanes to drive the pixels; and
signal lines disposed between the pixels, and
wherein a spacing between the backplanes or lengths of the backplanes are increased in a stretched state of the stretchable display.

5. The electronic device of claim 1, wherein the value of the operation parameter is determined to correspond to a value related to a stretching degree of the stretchable display, a value related to a change in a transmittance of the stretchable display, or a value related to a change in a light reception amount detected by the optical sensor.

6. The electronic device of claim 1, wherein the value of the operation parameter is determined to be proportional to or inversely proportional to a value related to a change in a transmittance of the stretchable display, a value related to a change in a light reception amount detected by the optical sensor, or a square of the value.

7. The electronic device of claim 1, wherein at least one of a light emission intensity, a light emission pulse frequency, a light emission pulse duty cycle, or a light emission time of the stretchable display is determined based on a value related to a stretching degree of the stretchable display.

8. The electronic device of claim 1, wherein the at least one processor is further configured to identify the value of the operation parameter corresponding to a value representing a stretching degree included in the tensile information based on a table including at least one of values representing stretching degrees, values related to transmittance changes or values related to changes in a light reception amount, or values of an operation parameter.

9. The electronic device of claim 1, wherein the at least one processor is further configured to:
compare a value representing a stretching degree included in the tensile information with a preset threshold value, and
when the value representing the stretching degree reaches the preset threshold value, control the at least one of the optical sensor or the stretchable display to operate based on the value of the operation parameter.

10. The electronic device of claim 1, wherein the at least one processor is further configured to, when the tensile information indicates an open state of the stretchable display, control the at least one of the optical sensor or the stretchable display to operate based on the identified or adjusted value of the operation parameter.

11. A method of operating an electronic device, the method comprising:
identifying tensile information of a stretchable display through a tensile information detection sensor;
identifying or adjusting a value of an operation parameter of at least one of an optical sensor or the stretchable display based on the tensile information; and
controlling at least one of the optical sensor or the stretchable display to operate based on the identified or adjusted value of the operation parameter.

12. The method of claim 11, wherein the identifying or adjusting of the value of the operation parameter comprises determining the value of the operation parameter to correspond to a value related to a stretching degree of the stretchable display, a value related to a change in a transmittance of the stretchable display, or a value related to a change in a light reception amount detected by the optical sensor.

13. The method of claim 11, further comprising determining at least one of a light emission intensity, a light emission pulse frequency, a light emission pulse duty cycle, or a light emission time of the stretchable display based on a value related to a stretching degree of the stretchable display.

14. The method of claim 11, wherein the controlling of the at least one of the optical sensor or the stretchable display comprises:
comparing a value representing a stretching degree included in the tensile information with a preset threshold value; and
when the value representing the stretching degree reaches the preset threshold value, controlling the at least one of the optical sensor or the stretchable display to operate based on the identified or adjusted value of the operation parameter.

15. The method of claim 11, wherein the controlling of the at least one of the optical sensor or the stretchable display comprises, when the tensile information indicates an open state of the stretchable display, controlling the at least one of the optical sensor or the stretchable display to operate based on the value of the operation parameter.
